(19) United States
(12) Patent Application Publication
(10) Pub. No.: US 2008/0258315 A1
(43) Pub. Date: Oct. 23, 2008

(54) SEMICONDUCTOR DEVICE AND PRODUCTION METHOD OF THE SAME SEMICONDUCTOR DEVICE

(75) Inventor: Sadayuki Okuma, Tokyo (JP)

Correspondence Address: YOUNG & THOMPSON, 209 Madison Street, Suite 500, ALEXANDRIA, VA, 22314, US

(73) Assignee: ELPIDA MEMORY , INC., TOKYO (JP)

(21) Appl. No.: 12/104,537

(22) Filed: Apr. 17, 2008

(30) Foreign Application Priority Data
Apr. 19, 2007 (JP) 2007-110483

(51) Int. Cl. H01L 23/48; H01L 21/44

(52) U.S. Cl. 257/784; 438/618; 257/E23.01; 257/E21.476

(57) ABSTRACT

The present invention aims to provide a semiconductor device which can enhance area efficiency, and the semiconductor device includes a plurality of electroconductive member regions formed in a predetermined layer, an insulating film region which is formed in the insulating layer which is an upper layer of the predetermined layer and which covers a region other than at least the plurality of electroconductive member regions, and wiring for making a connection which is formed along the insulating film region and which connects the plurality of electroconductive member regions mutually.

This application is based upon and claims the benefit of priority from Japanese Patent Application No. 2007-110483 filed on Apr. 19, 2007, the content of which is incorporated by reference.

### BACKGROUND OF THE INVENTION

1. Field of the Invention

The present invention relates to a semiconductor device, in which wiring, for which an ink jet method is used, is formed, and a production method thereof.

2. Description of the Related Art

In semiconductor devices, there is a circuit in which unnecessary wiring is cut from a plurality of wirings that are provided beforehand. In such circuits, for example, it is a fuse circuit for replacing defective memory by redundancy memory.

FIG. 1 is a circuit diagram illustrating an example of the construction of a fuse circuit. In addition, FIG. 2 is a layout pattern illustrating a layout example of fuse circuit 400 illustrated in FIG. 1.

Fuse circuit 400 comprises six N channel MOS (Metal Oxide Semiconductor) transistors 11 to 16 and six fuses 21 to 26, as illustrated in FIG. 1.

As for N channel MOS transistors 11 to 16, gates are connected with input terminals 111 to 116 respectively in pairs. Drains are connected to power supply terminal 101 via resistor 31 in common with output terminal 110. Sources are connected to GND terminal 102 respectively via fuses 21 to 26.

N channel MOS transistors 17 to 19 illustrated in FIG. 2 are equivalent to N channel MOS transistors 11 and 12, N channel MOS transistors 13 and 14, and N channel MOS transistors 15 and 16, which are illustrated in FIG. 1, respectively. In addition, P channel MOS transistor 32 is equivalent to resistor 31. In addition, the size described in FIG. 2 shows the length that is necessary for the layout of a fuse.

For example, fuse circuit 400 is designed in which the an output state of output terminal 110 becomes high-level when a high-level signal is inputted into input terminal 113, and thus the cutting of fuse 23 by a laser beam is performed as illustrated in FIG. 1.

In addition, as a semiconductor device comprising a circuit such as fuse circuit 400, a semiconductor device is proposed in which a degree of integration is enhanced without causing damage to an adjacent fuse when laser beam cutting takes place, and, for example, Japanese Patent Laid-Open No. 2000-150832 (hereinafter, this is called document 1) is disclosed.

In the semiconductor device described in document 1, a plurality of fuses whose form is devised so that intervals between fuses may be narrow in a portion where laser beam cutting is not performed, but may be wide in a portion where laser beam cutting is performed is laid out. Thereby, it becomes possible to improve the degree of integration of fuses without an adjacent fuse receiving damage at the time when laser beam cutting takes place.

However, in case of using a fuse as means of changing a circuit operation, it is not possible to arrange another element around the fuse because laser beam cutting takes place. Therefore, there is a problem that area efficiency of a circuit is low.

### SUMMARY OF THE INVENTION

It is an object of the present invention to provide a semiconductor device, which can enhance area efficiency, and a production method of the semiconductor device.

To achieve the above object, the semiconductor device of the present invention includes a plurality of electroconductive member regions formed in a predetermined layer, an insulating film region which is formed in an insulating layer which is an upper layer of the predetermined layer and which covers regions other than at least the plurality of electroconductive member regions, and wiring for making a connection which is formed along the insulating film region and which connects the plurality of electroconductive member regions mutually.

In addition, to achieve the above object, the production method of the semiconductor device of the present invention includes firstly forming a plurality of electroconductive member regions in a predetermined layer, secondly forming in an upper layer of the predetermined layer an insulating film region which covers one or more regions other than the plurality of electroconductive member regions, and thirdly forming wiring for making a connection which connects the plurality of electroconductive member regions mutually along the insulating film region.

The above and other objects, features, and advantages of the present invention will become apparent from the following description with reference to the accompanying drawings which illustrate examples of the present invention.

### BRIEF DESCRIPTION OF THE DRAWINGS

FIG. 1 is a circuit diagram illustrating an example of a fuse circuit.

FIG. 2 is a layout pattern illustrating a layout example of the fuse circuit;

FIG. 3 is a circuit diagram illustrating an exemplary embodiment of a connection switching circuit;

FIG. 4 is an exemplary embodiment of layout pattern illustrating of the connection switching circuit;

FIG. 5A is a top view illustrating a state of pads before wiring is formed, FIG. 5B is a sectional view illustrating a state of the pads before wiring is formed, and FIG. 5C is a sectional view illustrating a case where a groove is formed;

FIG. 6A is a top view illustrating a form of the wiring, and FIG. 6B is a sectional view illustrating the form of wiring;

FIG. 7 is a view illustrating of wiring forming process;

FIG. 8 is a view illustrating of a semiconductor wafer in which the wiring is formed using an ink jet printer;

FIG. 9 is a circuit diagram illustrating one structural example of a connection switching circuit;

FIG. 10 is a circuit diagram illustrating one structural example of a connection switching circuit;

FIG. 11 is a layout pattern illustrating a layout example of the connection switching circuit; and

FIG. 12 is a layout pattern illustrating that an N channel MOS transistor of another circuit is arranged, in the layout pattern of FIG. 11.

### DETAILED DESCRIPTION OF THE PREFERRED EMBODIMENTS

A semiconductor device of exemplary embodiment comprises a connection switching circuit.

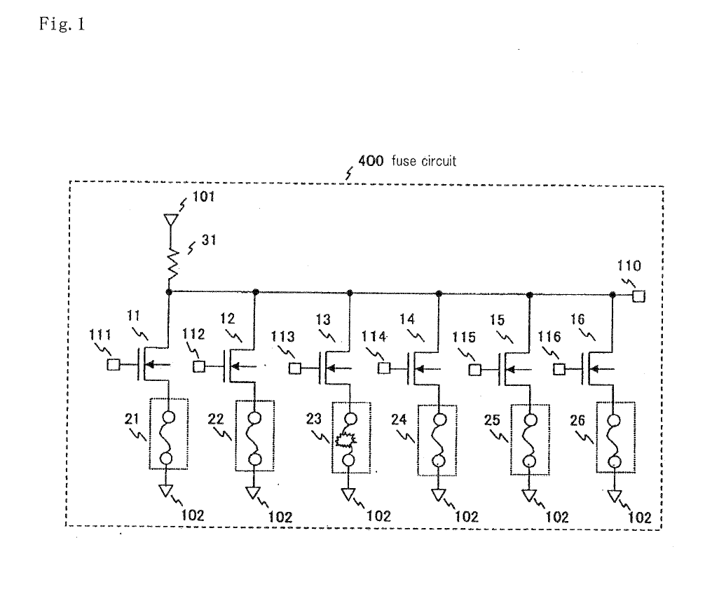

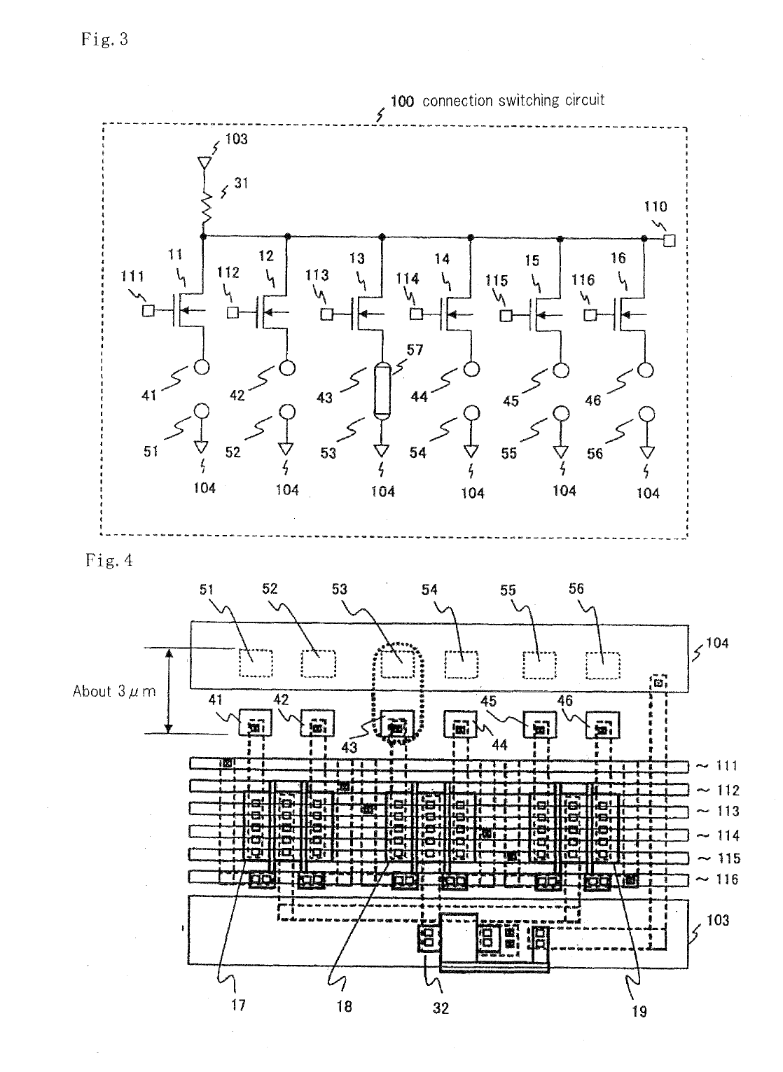

FIG. 3 is a circuit diagram illustrating an exemplary embodiment of a connection switching circuit. In addition, FIG. 4 is an exemplary embodiment of layout pattern illustrating of the connection switching circuit. In addition, the same reference numerals are assigned to the same construction as the construction of fuse circuit 400 illustrated in FIG. 1 and their detailed descriptions are omitted.

Connection switching circuit 100 illustrated in FIG. 3 comprises six N channel MOS transistors 11 to 16, pads 41 to 46 corresponding to and being connected to respective sources of N channel MOS transistors 11 to 16, and pads 51 to 56 grounded via GND terminal 104. Each part is arranged as shown in the layout pattern illustrated in FIG. 4.

As for N channel MOS transistors 11 to 16 illustrated in FIG. 3, their gates are connected to input terminals 111 to 116 respectively in pairs. Drains are commonly connected to power supply terminal 103 via resistor 31 with output terminal 110. In addition, any one of input terminals 111 to 116 is given a high level signal.

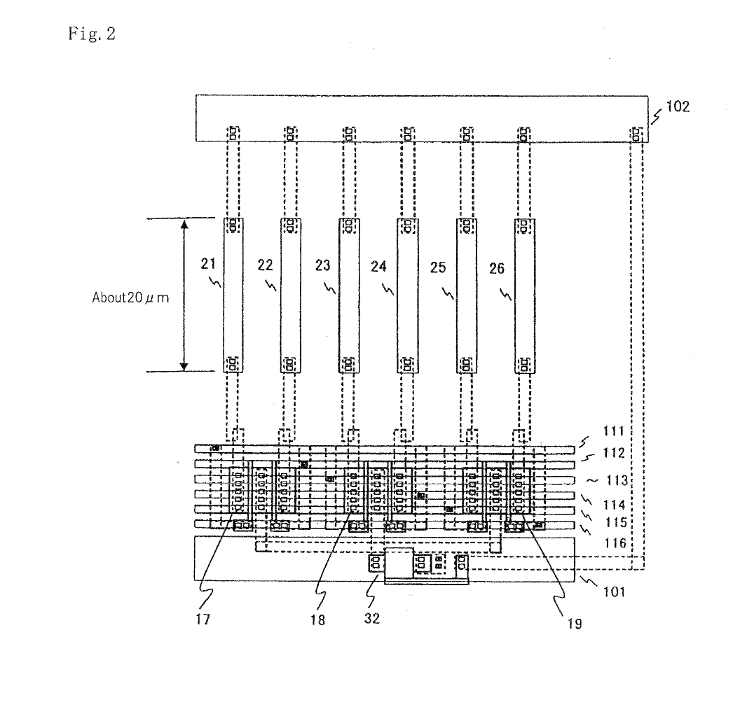

A size (about 3 μm) described in FIG. 4 means forming a required length of wiring between the pads. In comparison with the layout pattern in FIG. 2, connection switching circuit 100 can form wiring in an area smaller than that of fuse circuit 400. This is because, in connection switching circuit 100, it is not necessary to cut the wiring at the time of changing the circuit operation unlike fuse circuit 400.

Pads 41 to 46 and pads 51 to 56 are in respective pair relationships, and according to a design of connection switching circuit 100, two corresponding pads are connected a wiring. For example, when connection switching circuit 100 is designed that an output state of output terminal 110 becomes low-level when a high-level signal is inputted into input terminal 113, wiring 57 which connects pads 43 and 53 is formed as illustrated in FIG. 3.

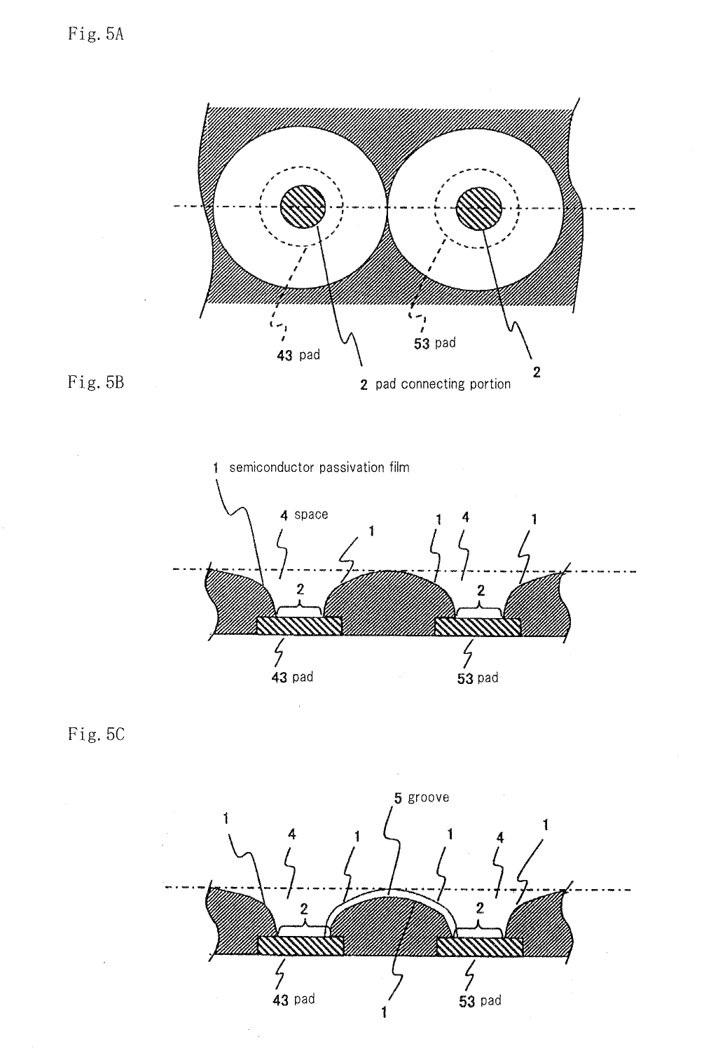

Next, a forming method and a process for forming wiring 57 will be described with reference to FIG. 5 to FIG. 7.

FIG. 5A is a top view illustrating an example of states of pads 43 and 53 before wiring 57 is formed. FIG. 5B is a sectional view illustrating an example of states of pad 43 and pad 53 before wiring 57 is formed.

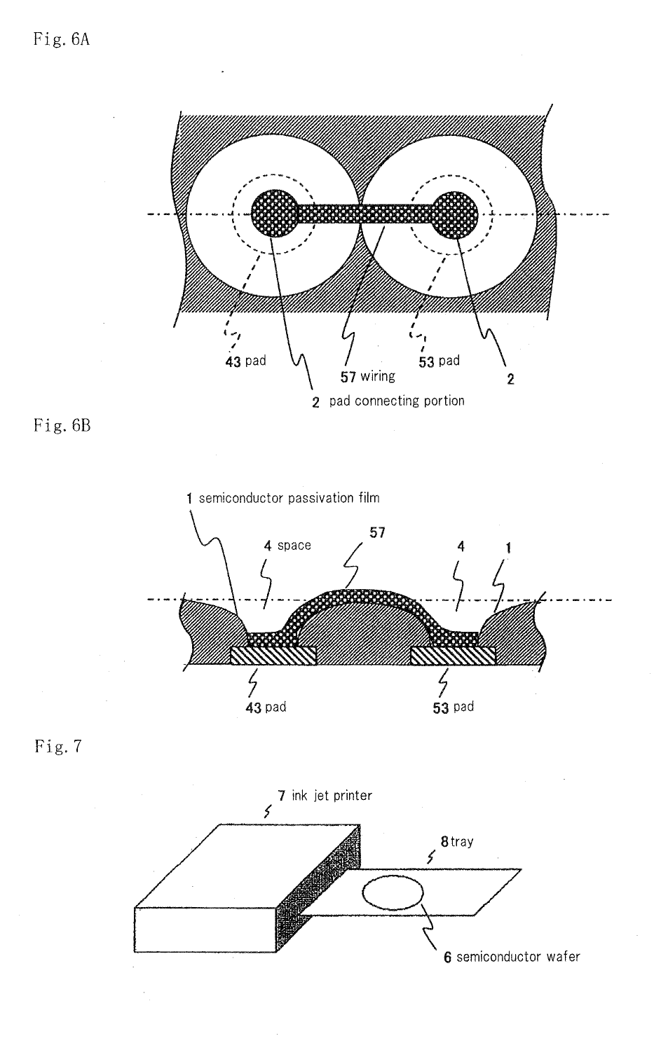

FIG. 6A is a top view illustrating a process for forming wiring 57. FIG. 6B is a sectional view illustrating a process for forming wiring 57.

In addition, pad 43 has been connected with wiring beforehand with a source of N channel MOS transistor 13. Because a process for forming the wiring is not particularly limited, its description is omitted in FIG. 5 and FIG. 6.

FIG. 7 illustrates an example of forming process of wiring 57.

Semiconductor passivation film 1 contacts with pad connecting portion 2 on an upper face of pad 43, as illustrated in FIG. 5A and FIG. 5B.

In addition, space 4 has been formed on the upper face of pad 43 before wiring 57 is formed. In addition, similarly to pad 43, space 4 has been formed on an upper face of pad 53 before wiring 57 is formed.

Semiconductor wafer 6 illustrated in FIG. 7 is divided into a plurality of chips. In addition, connection switching circuit 100, before wiring is formed, is generated in each chip. Then, ink jet printer 7 which can inject a liquid, in which metal particles, such as silver, are contained, forms wiring 57 in a predetermined position on semiconductor wafer 6 mounted on tray 8.

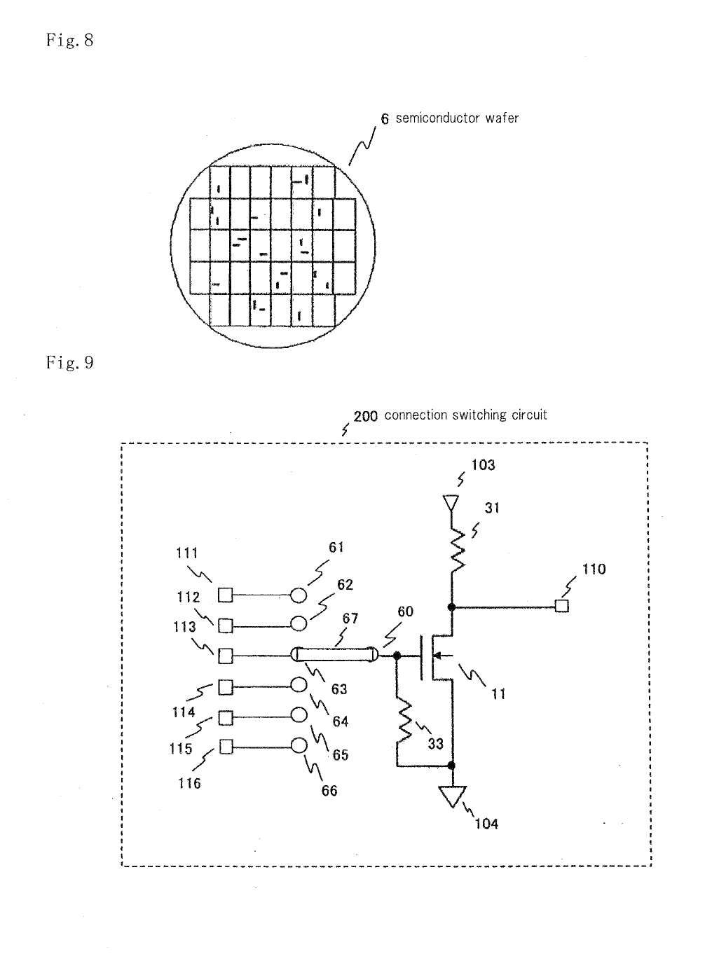

In addition, since it is possible to specify a position, where wiring is formed, when ink jet printer 7 is used, for example, as illustrated in FIG. 8, it is also possible to form wiring at a different position in every chip.

As illustrated in FIG. 6A and 6B, wiring 57 is formed such that the metal particles contained in the liquid injected from ink jet printer 7 adhere to each upper face of semiconductor passivation film 1 and pads 43 and 53.

In addition, as illustrated in FIG. 5C, it is also sufficient to make semiconductor passivation film 1 into a form in which groove 5 is on a line connecting pad 43 and pad 53. In this case, since the surface area of semiconductor passivation film 1 increases and the volume of wiring can be increased, it becomes possible to reduce the resistance of the wiring.

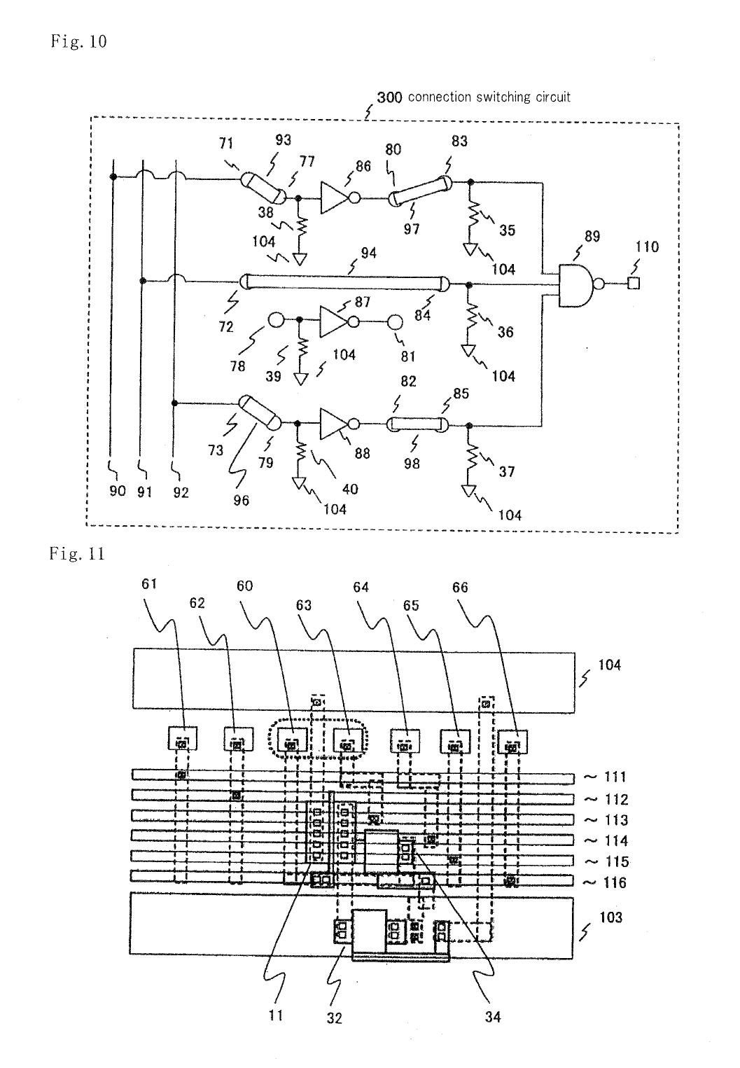

Furthermore, other than connection switching circuit 100, a circuit whose wiring is formed using ink jet printer 7 may be used as connection switching circuit 200 as illustrated in FIG. 9, or connection switching circuit 300 as illustrated in FIG. 10. In addition, in FIG. 9 and FIG. 10, as regards the same parts illustrated FIG. 3, the same reference numerals are applied and their detailed descriptions are omitted.

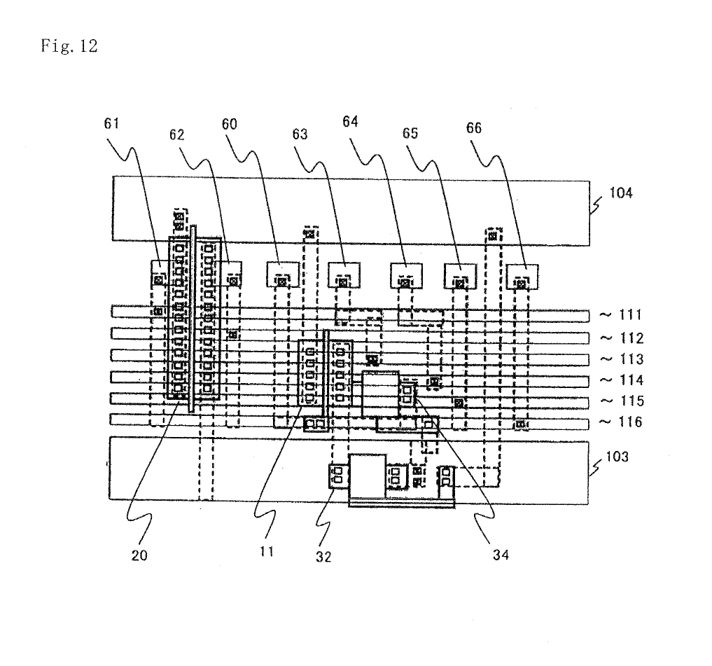

Connection switching circuit 200 comprises N channel MOS transistor 11 and pads 60 to 66, as illustrated in FIG. 9. Then, each part is arranged, for example, as illustrated in the layout pattern illustrated in FIG. 11.

As for N channel MOS transistor 11 illustrated in FIG. 9, a gate is connected to GND terminal 104 via resistor 33 with pad 60. A drain is connected to power supply terminal 103 via resistor 31 with output terminal 110. In addition, source is connected to GND terminal 104. Furthermore, P channel MOS transistor 34 illustrated in FIG. 11 is equivalent to resistor 33.

Pads 61 to 66 are connected with input terminals 111 to 116 in pairs. In addition, similarly to connection switching circuit 100, semiconductor passivation film 1 as illustrated in FIG. 5 is provided in each pad.

In connection switching circuit 200, wiring which connects any one of pads 61 to 66 and pad 60 according to the design of connection switching circuit 200 is formed by the same method as that of wiring 57.

For example, connection switching circuit 200 is designed such that an output state of output terminal 110 becomes low-level when a high-level signal is inputted into input terminal 113. In this case, as illustrated in FIG. 9, wiring 67 which connects pad 63 and pad 60 is formed by the same method as that of wiring 57.

In the case of connection switching circuit 200, the same operation as that of connection switching circuit 100 is performed in one N channel MOS transistor. Thereby, since reduce the number of N channel MOS transistors, it becomes possible to perform a high-speed operation with low power consumption in comparison with connection switching circuit 100.

In addition, as illustrated in the layout pattern in FIG. 11, a space is obtained with reduction of N channel MOS transistors. Then, for example, as in the layout pattern illustrated in FIG. 12, when N channel MOS transistor 20 which is a circuit element that is different from connection switching circuit 200 is arranged in the obtained space, the layout area of the whole circuit is reducible. In consequence, it becomes possible to further miniaturize a device.

Furthermore, since wiring formation using an ink jet method does not give damage to a semiconductor, an element and wiring can be arranged under a pad or ink jet wiring, and hence, this is effective for increasing the efficiency of the layout.

Connection switching circuit 300 comprises pads 71 to 85, inverting circuits 86 to 88, and NAND circuit 89, as illustrated in FIG. 10. In addition, similarly to connection switching circuit 100, semiconductor passivation film 1 as illustrated in FIG. 5 is provided in each pad.

Pad 71 is connected with word lines 90. Pad 72 is connected with word lines 91. Pad 73 is connected with word lines 92.

Pad 77 is a node in the input side of inverting circuit 86, and is connected to GND terminal 104 via resistors 38 for prevention a floating electric potential of a node. Pad 78 is a node in an input side of inverting circuit 87, and is connected to GND terminal 104 via resistors 39 for prevention a floating electric potential of a node. Pad 78 is a node in an input side of inverting circuit 88, and is connected to GND terminal 104 via resistors 40 for prevention a floating electric potential of a node.

Pads 80 to 82 are connected to an output side of inverting circuits 86 to 88 respectively.

Respective pads 83 to 85 are nodes in an input side of NAND circuits 89, and are connected to GND terminal 104 via resistors 35 to 37 respectively. In addition, an output side of NAND circuit 89 is connected to output terminal 110.

For example, connection switching circuit 300 is designed such that an output state of output terminal 110 becomes low-level when low-level, high-level, and low-level signals are inputted into word lines 90, 91, and 92 respectively. In this case, as illustrated in FIG. 10, wirings 93 to 98 are formed respectively by the same method as that of wiring 57.

In addition, wiring 93 is wiring which connects pad 71 to pad 77. Wiring 94 is wiring which connects pad 72 to pad 84. Wiring 96 is wiring which connects pad 73 to pad 79. Wiring 97 is wiring which connects pad 80 to pad 83. Wiring 98 is wiring which connects pad 82 to pad 85.

In connection switching circuit 300, it becomes possible to perform the same operation as that of connection switching circuit 100 with a simplified wiring pattern.

According to the invention, since the process of forming wiring is performed using an ink jet method instead of a fuse, no damage is caused to the base, but it is possible to arrange a circuit and wiring under a connection switching circuit region, and hence, it becomes possible to increase the area efficiency. For example, it becomes possible to achieve redundant memory circuits, such as DRAM (Dynamic Random Access Memory), in a small area.

In addition, although the construction of making wiring formed by an ink jet method as a top layer is shown to facilitate easy understanding in each embodiment mentioned above, a film including functions, such as an overcoat, is actually formed.

While preferred embodiments of the present invention have been described using specific terms, such description is for illustrative purposes only, and it is to be understood that changes and variations may be made without departing from the spirit or scope of the following claims.

What is claimed is:

1. A semiconductor device comprising:
a plurality of electroconductive member regions formed in a predetermined layer;
an insulating film region which is formed in an insulating layer which is an upper layer of said predetermined layer and which covers a region other than at least said plurality of electroconductive member regions; and
wiring for making a connection which is formed along said insulating film region and which connects said plurality of electroconductive member regions mutually.

2. The semiconductor device according to claim 1, wherein said wiring for making a connection is wiring formed using an ink jet method.

3. The semiconductor device according to claim 1, wherein said plurality of electroconductive member regions are arranged adjacently.

4. The semiconductor device according to claim 2, wherein said plurality of electroconductive member regions are arranged adjacently.

5. The semiconductor device according to claim 1, wherein said predetermined layer is a top layer of an electroconductive member, said insulating layer is a first surface protective layer of the semiconductor device, and a second surface protective layer is provided over a whole upper layer of said insulating layer and said wiring for making a connection.

6. The semiconductor device according to claim 2, wherein said predetermined layer is a top layer of an electroconductive member, said insulating layer is a first surface protective layer of the semiconductor device, and a second surface protective layer is provided over a whole upper layer of said insulating layer and said wiring for making a connection.

7. The semiconductor device according to claim 3, wherein said predetermined layer is a top layer of an electroconductive member, said insulating layer is a first surface protective layer of the semiconductor device, and a second surface protective layer is provided over a whole upper layer of said insulating layer and said wiring for making a connection.

8. The semiconductor device according to claim 4, wherein said predetermined layer is a top layer of an electroconductive member, said insulating layer is a first surface protective layer of the semiconductor device, and a second surface protective layer is provided over a whole upper layer of said insulating layer and said wiring for making a connection.

9. A production method of a semiconductor device, comprising:
firstly forming a plurality of electroconductive member regions in a predetermined layer;
secondly forming in an upper layer of the predetermined layer an insulating film region which covers one or more regions other than the plurality of electroconductive member regions; and
thirdly forming wiring for making a connection which connects the plurality of electroconductive member regions mutually along the insulating film region.

10. The production method of a semiconductor device according to claim 5, wherein the step of thirdly forming uses an ink jet method.
